(19) United States
(12) Patent Application Publication
(10) Pub. No.: US 2025/0323136 A1
(43) Pub. Date: Oct. 16, 2025

(54) INTEGRATED CIRCUIT (IC) PACKAGE INCLUDING TWO SUBSTRATES AND VERTICAL INTERCONNECTS COUPLING THE TWO SUBSTRATES, THE VERTICAL INTERCONNECTS COMPRISING A METAL BALL AND METAL PIN COMBINATION TO ADDRESS AN INCREASED DISTANCE BETWEEN SUBSTRATES

(71) Applicant: QUALCOMM Incorporated, San Diego, CA (US)

(72) Inventors: Zhijie Wang, San Diego, CA (US); Joan Rey Villarba Buot, Escondido, CA (US); Aniket Patil, San Diego, CA (US)

(21) Appl. No.: 18/633,667

(22) Filed: Apr. 12, 2024

(51) Int. Cl. H01L 23/498; H01L 23/00; H01L 25/00; H01L 25/10

(52) U.S. Cl. CPC H01L 23/49838; H01L 23/49833; H01L 23/49866; H01L 25/105; H01L 25/50; H01L 24/24; H01L 2224/24225; H01L 2924/1815

(57) ABSTRACT

Aspects disclosed include an integrated circuit (IC) package including two substrates and vertical interconnects coupling the two substrates, the vertical interconnects comprising a metal ball and metal pin combination to address an increased distance between substrates. The vertical interconnects are disposed in a mold layer between the two substrates. The mold layer also includes a die, a plurality of metal pins, and a plurality of metal balls coupled to the plurality of metal pins to form the vertical interconnects. Larger distances between the two substrates are desirable when a die's thickness is increased to increase thermal dissipation from the die. As an example, by utilizing a plurality of metal ball and pin combinations as vertical interconnects, larger distances between the two substrates may be advantageously achieved with reduced risk of electrical shorting between vertical interconnects and without compromising pitch between vertical interconnects.

### TECHNICAL FIELD

The field of the disclosure relates to integrated circuit (IC) packages, and more particularly to design and manufacture of package substrates that support signal routing to a semiconductor die(s) in the IC package.

### BACKGROUND

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The package substrate includes one or more metallization layers that include metal interconnects (e.g., metal traces, metal lines) with vertical interconnect accesses (vias) coupling the metal interconnects together between adjacent metallization layers to provide electrical interfaces between the die(s). The die(s) is electrically interfaced to metal interconnects exposed in a top or outer layer of the package substrate to electrically couple the die(s) to the metal interconnects of the package substrate. The package substrate includes an outer metallization layer coupled to external metal interconnects (e.g., solder bumps) to provide an external interface between the die(s) in the IC package for mounting the IC package on a circuit board to interface the die(s) with other circuitry. The package substrate may include an embedded trace substrate (ETS) (or include a thin ETS metallization layer) adjacent to the die to facilitate higher density bump/solder joints for coupling the die(s) to the package substrate.

Some IC packages are known as “hybrid” IC packages. Hybrid IC packages include multiple dies for different purposes or applications. For example, a hybrid IC package may include an application die, such as a communications modem or processor (including a system). The hybrid IC package could also include one or more memory dies to provide memory to support data storage and access by the application die. The multiple dies can be provided in their own respective die packages that are stacked on top of each other within an overall IC package to reduce the cross-sectional area of the package, known as a stacked-die IC package. In a stacked-die IC package, a first die package is provided that includes a first, bottom die supported by a first, bottom substrate. First die interconnects of the first die are coupled to metal interconnects in the first substrate that are connected to external interconnects (e.g., solder bumps) and other interface interconnects to provide an electrical signal interface to the first die. A second die package that includes a second die is stacked above the first die package in the stacked-die IC package. The second die is electrically coupled through second die interconnects to metal interconnects in a second substrate of the second die package. To provide support and interconnectivity between the second die package and the first die package for die-to-die (D2D) connections as well as between the second die and the external interconnects, the first die package can include an interposer substrate that is disposed adjacent to the first die between the first die package and the second die package. The second die package is coupled to the interposer substrate to provide a connection interface between the first die package and the second die package for D2D and external connections.

### SUMMARY OF THE DISCLOSURE

Aspects disclosed in the detailed description include an integrated circuit (IC) package including two substrates and vertical interconnects coupling the two substrates, the vertical interconnects comprising a metal ball and metal pin combination to address an increased distance between substrates. The vertical interconnects are disposed in a mold layer between the two substrates. The mold layer also includes a die, a plurality of metal pins, and a plurality of metal balls coupled to the plurality of metal pins to form the vertical interconnects. In one example, larger distances between the two substrates are desirable when the thickness of a die is increased to increase thermal dissipation from the die. Increasing a die's thickness results in an increased distance between the two substrates because a minimal distance is needed to inject mold in the mold layer between the die and one of the two substrates. As an example, by utilizing a plurality of metal ball and pin combinations as vertical interconnects, larger distances between the two substrates may be advantageously achieved with reduced risk of electrical shorting between vertical interconnects and without compromising pitch between vertical interconnects.

In this regard in one aspect, an integrated circuit (IC) package, comprising a first substrate and a second substrate. The first substrate comprises a first metallization layer extending in a first direction. The second substrate comprises a second metallization layer extending in the first direction and a mold layer extending in the first direction. The mold layer comprises a die coupled to one of the first substrate or the second substrate, a plurality of metal balls coupled to the first metallization layer, and a plurality of metal pins coupled to the plurality of metal balls, the plurality of metal pins coupled to the second metallization layer.

In this regard in one aspect, a method of fabricating an integrated circuit (IC) package for addressing an increased distance between two substrates. The method comprises fabricating a first substrate including a first metallization layer extending in a first direction, fabricating a second substrate including a second metallization layer extending in the first direction, and fabricating a mold layer extending in the first direction wherein fabricating the mold layer comprises fabricating a die, fabricating a plurality of metal balls, and fabricating a plurality of metal pins. The method further comprises coupling the die to one of the first substrate or the second substrate, coupling the plurality of metal balls to the first metallization layer, coupling the plurality of metal pins to the plurality of metal balls, and coupling the plurality of metal pins to the second metallization layer.

### BRIEF DESCRIPTION OF THE FIGURES

FIG. 1A is a side view of an exemplary three-dimensional (3D) integrated circuit (IC) (3DIC) package that includes two substrates and vertical interconnects coupling the two substrates, the vertical interconnects comprising a metal ball and metal pin combination to address an increased distance between the two substrates;

FIG. 1B is a close-up view of FIG. 1A;

FIG. 2 is a side view of an exemplary package-on-package 3DIC package that includes two substrates and vertical interconnects coupling the two substrates, the vertical interconnects comprising a metal ball and metal pin combination to address an increased distance between the two substrates;

FIG. 3 is a side view of another exemplary three-dimensional (3D) integrated circuit (IC) (3DIC) package that includes two substrates and vertical interconnects coupling the two substrates, the vertical interconnects comprising a metal ball and metal pin combination to address an increased distance between the two substrates;

FIG. 4 is a flowchart illustrating an exemplary fabrication process of fabricating a 3DIC package such as the 3DIC packages in FIGS. 1A, 1B, and 2, wherein the 3DIC package includes two substrates and vertical interconnects coupling the two substrates, the vertical interconnects comprising a metal ball and metal pin combination to address an increased distance between the two substrates, including, but not limited to, the 3DIC packages in FIGS. 1A, 1B, 2, and 3;

FIG. 5 is a flowchart illustrating an exemplary fabrication process of fabricating a first substrate, wherein the first substrate includes a plurality of metal balls for forming vertical interconnects which address an increased distance between two substrates, including, but not limited to, the increased distance between the two substrates in the 3DIC packages in FIGS. 1A, 1B, 2, and 3;

FIGS. 6A-6B are exemplary fabrication stages during fabrication of the first substrate according to the fabrication process in FIG. 5;

FIG. 7 is a flowchart illustrating an exemplary fabrication process of fabricating a second substrate, wherein the second substrate includes a plurality of metal pins for forming vertical interconnects which address an increased distance between two substrates, including, but not limited to, the increased distance between the two substrates in the 3DIC packages in FIGS. 1A, 1B, 2, and 3;

FIGS. 8A-8B are exemplary fabrication stages during fabrication of the second substrate according to the fabrication process in FIG. 7;

FIG. 9 is a flowchart illustrating an exemplary assembly process of fabricating a package utilizing the first substrate fabricated in FIG. 6B and the second substrate fabricated in FIG. 8B to form a 3DIC package including, but not limited to, the 3DIC packages in FIGS. 1A, 1B, 2, and 3 which include vertical interconnects having a metal ball and metal pin combination to address an increased distance between the two substrates;

FIGS. 10A-10B are exemplary assembly stages during assembly of the package according to the fabrication process in FIG. 9;

FIG. 11 is a block diagram of an exemplary wireless communications device that includes radio-frequency (RF) components deployed in an IC package, wherein the IC package includes two substrates and vertical interconnects coupling the two substrates, the vertical interconnects comprising a metal ball and metal pin combination to address an increased distance between the two substrates, including, but not limited to, the 3DIC packages in FIGS. 1A, 1B, 2, and 3 and according to the exemplary fabrication processes in FIGS. 4, 5, 7, and 9; and

FIG. 12 is a block diagram of an exemplary processor-based system that can include components deployed in an IC package, wherein the IC package includes two substrates and vertical interconnects coupling the two substrates, the vertical interconnects comprising a metal ball and metal pin combination to address an increased distance between the two substrates, including, but not limited to, the 3DIC packages in FIGS. 1A, 1B, 2, and 3 and according to the exemplary fabrication processes in FIGS. 4, 5, 7, and 9.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects. The term “adjacent” as used herein means spatially next to but not necessarily adjoining something as shown in the Figures unless specifically stated otherwise.

Aspects disclosed in the detailed description include an integrated circuit (IC) package including two substrates and vertical interconnects coupling the two substrates, the vertical interconnects comprising a metal ball and metal pin combination to address an increased distance between substrates. The vertical interconnects are disposed in a mold layer between the two substrates. The mold layer also includes a die, a plurality of metal pins, and a plurality of metal balls coupled to the plurality of metal pins to form the vertical interconnects. In one example, larger distances between the two substrates are desirable when the thickness of a die is increased to increase thermal dissipation from the die. Increasing a die's thickness results in an increased distance between the two substrates because a minimal distance is needed to inject mold in the mold layer between the die and one of the two substrates. As an example, by utilizing a plurality of metal ball and pin combinations as vertical interconnects, larger distances between the two substrates may be advantageously achieved with reduced risk of electrical shorting between vertical interconnects and without compromising pitch between vertical interconnects.

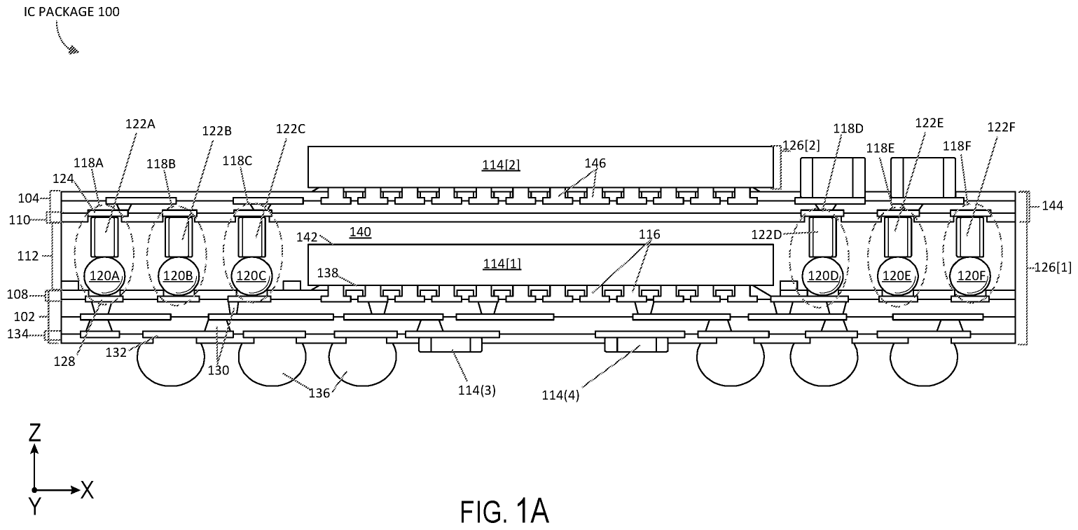

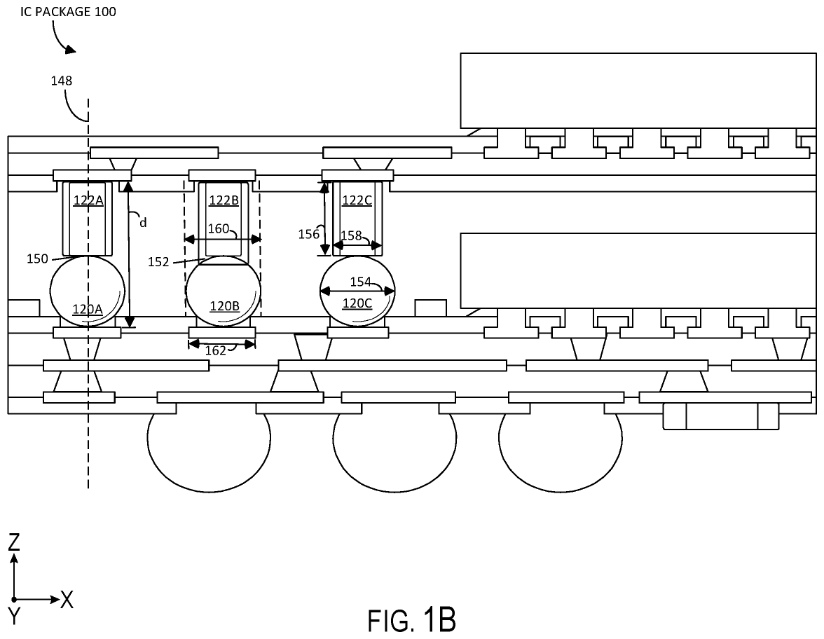

In this regard, FIG. 1A is a side view of an exemplary three-dimensional (3D) IC (3DIC) package 100 that includes two substrates and vertical interconnects coupling the two substrates, the vertical interconnects comprising a metal ball and metal pin combination to address an increased distance between the two substrates. The two substrates include a package substrate 102 and an interposer substrate 104, both of which extend in a first, horizontal direction (X-, Y-axes direction). The package substrate 102 and the interposer substrate 104 commonly route signals and power and, for convenience, may both be referred to simply as a substrate. The first, package substrate 102 includes a first, upper metallization layer 108 extending in the first, horizontal direction. The second, interposer substrate 104 includes a second, bottom metallization layer 110. A mold layer 112 extending in the first, horizontal direction includes a first die 114(1) coupled to one of the first substrate 102 or the second substrate 104. In this example, the first die 114(1) is coupled to the first, upper metallization layer 108 of the first substrate 102 through die interconnects 116. The mold layer 112 also includes vertical interconnects 118A-118F which are coupled to the package substrate 102 and to the interposer substrate 104. The vertical interconnects 118A-118F comprise a plurality of metal balls 120A-120F coupled to a plurality of metal pins 122A-122F. The plurality of metal balls 120A-120F are coupled to the first, upper metallization layer 108 in the package substrate 102. In this example, the first die 114(1) is directly coupled to substrate 102 which is directly coupled to the plurality of metal balls 120A-120F through the first, upper metallization layer 108. The plurality of metal pins 122A-122F are coupled to the second, bottom metallization layer 110 and, in particular, to metal interconnects 124 (e.g., pads) formed in the bottom metallization layer 110. Six vertical interconnects 118A-118F are shown for simplicity, but many more may exist between the first substrate 102 and the second substrate 104 and are limited by the width of the vertical interconnects 118A-118F which will be discussed further in connection with FIG. 1B. The metal balls 120A-120F and the metal pins 122A-122F are preferably comprised of copper (Cu).

The IC package 100 includes the first die 114(1) and a second die 114(2) that are included in respective first and second die packages 126(1), 126(2) and are stacked on top of each other in a second, vertical direction (Z-axis direction). The first die package 126(1) of the IC package 100 includes the first die 114(1) coupled to the package substrate 102. The first, upper metallization layer 108 provides an electrical interface for signal routing to the first die 114(1). The first die 114(1) is coupled to the die interconnects 116 (e.g., raised metal bumps, pillars) that are electrically coupled to metal interconnects 128 (e.g., metal pads) in the first, upper metallization layer 108. The metal interconnects 128 in the first, upper metallization layer 108 are coupled to metal vias 130 in the package substrate 102, which are coupled to metal interconnects 132 (e.g. metal pads) in a first, bottom metallization layer 134 of the package substrate 102. In this manner, the package substrate 102 provides interconnections between its first, upper metallization layer 108 and first, bottom metallization layer 134 to provide signal routing to/from the first die 114(1) from/to the second die 114(2) and vice versa. External interconnects 136 (e.g., ball grid array (BGA) interconnects) are coupled to the metal interconnects 132 in the bottom metallization layer 134 to provide interconnections through the package substrate 102 to the first die 114(1) through the die interconnects 116. In this example, a first, active side 138 of the first die 114(1) is adjacent to and coupled to the package substrate 102, and more specifically the first, upper metallization layer 108 of the package substrate 102.

A third die 114(3) and fourth die 114(4) are attached to the bottom side of the first die package 126(1). The third die 114(3) and the fourth die 114(4) can be any silicon or gallium arsenide electrical device. Typical widths in the second direction of the third die 114(3) and the fourth die 114(4) are on the order of 100 microns. The third die 114(3) and the fourth die 114(4) include die connects (not shown) which couple to the metal interconnects 128 in the bottom metallization layer 134.

In the exemplary IC package 100 in FIG. 1, the second die package 126(2) is provided and coupled to the first die package 126(1) to support multiple dies. For example, the first die 114(1) in the first die package 126(1) may include an application processor, and the second die 114(2) may be a memory die, such as a dynamic random access memory (DRAM) die that provides memory support for the application processor. In this regard, in this example, the first die package 126(1) also includes the interposer substrate 104 that is disposed in the mold layer 112 which includes a package mold 140 encasing the first die 114(1), adjacent to an inactive side 142 of the first die 114(1). The interposer substrate 104 also includes one or more metallization layers 144 including the bottom metallization layer 110 to provide interconnections to the second die 114(2) in the second die package 126(2). The second die 114(2) is physically and electrically coupled to the first die package 126(1) through die connects 146 coupled to the metallization layers 144 in the interposer substrate 104.

FIG. 1B is a close-up view of FIG. 1A. The distance d between the package substrate 102 and the interposer substrate 104 is at least 300 micrometers (μm). At this distance d and beyond, conventional metal balls to couple the two substrates present a high risk of shorting each other because the diameter of a conventional metal ball approximates the distance d between substrates creating a wide profile in the X-, Y-axes direction and limiting the number of vertical interconnects to be utilized in a given space. Alternatively, conventional metal pins also present a manufacturing challenge at this distance and beyond. To manufacture conventional metal pins with acceptable reliability, metal pins need to be limited to a 3:1 length to width ratio. At the distance d the width of a metal pin would increase the risk of shorting between vertical interconnects, and thus would require an increase in the distance between vertical interconnects (a.k.a. pitch) limiting the number of vertical interconnects in a given space. Unlike conventional metal balls and metal pins, the vertical interconnects 118A-118F include metal balls 120A-120F coupled to metal pins 122A-122F, respectively. The metal balls 120A-120F are aligned with the metal pins 122A-122F, respectively, through a common vertical axis 148 in the Z-axis direction. For example, metal ball 120A is aligned with metal pin 122A through the vertical axis 148, which is along the center axis of both the metal ball 120A and the metal pin 122A. The metal balls 120A-120F are attached to the metal pins 122A-122F, respectively, through either a compression joint 150 or a solder joint 152. Although both types of joints are shown for exemplary purposes in the same FIG. 1B, the same type of joint would be used for a particular manufactured package.

The metal balls 120A-120F have a diameter 154 of between 100 micrometers (μm) and 135 μm. When the metal balls 120A-120F are composed primarily of copper (Cu), the diameter 154 is closer to 100 μm. When the metal balls 120A-120F are composed primarily of Cu and tin (Sn), the diameter 154 is closer to 135 μm. The metal pins 122A-122F have a width 158 in the first, horizontal direction (X-, Y-axes direction) of between 100 micrometers (μm) and 135 μm, with the width 158 being approximately equal to the diameter 154 and a length 156 in the second, vertical direction (Z-axis direction) of approximately 300 μm. The diameter 154 and width 158 are each individually less than the distance d between the first substrate 102 and the second substrate 104. The length 156 may be in a range between 100 μm and 400 μm. The diameter 154 and width 158 may be in a range between 80 μm and 180 μm. By the diameter 154 and width 158 being equal, a width profile 160 of the vertical interconnect which is also equal to the diameter 154 and width 158 is reduced resulting in a reduced metal interconnect width 162 of the metal interconnects 128 formed in the first metallization layer 108 of the first substrate 102 and the metal interconnects 124 formed in the second metallization layer 110 of the second substrate 104. The metal interconnect width 162 is 130 μm and is approximately equal to the width profile 160 of the vertical interconnect and may depend on the pitch spacing and line/space needed in between metal interconnects.

The reduced width profile 160 of the vertical interconnect and reduced width 162 of the metal interconnects 124, 128 enable tighter pitch between vertical interconnects 118A-118F, and thus allows an increased number of vertical interconnects in a given space, which is especially advantageous when the second die 114(2) is a memory die requiring in increased number of input/output (I/O) connections which are carried through vertical interconnects.

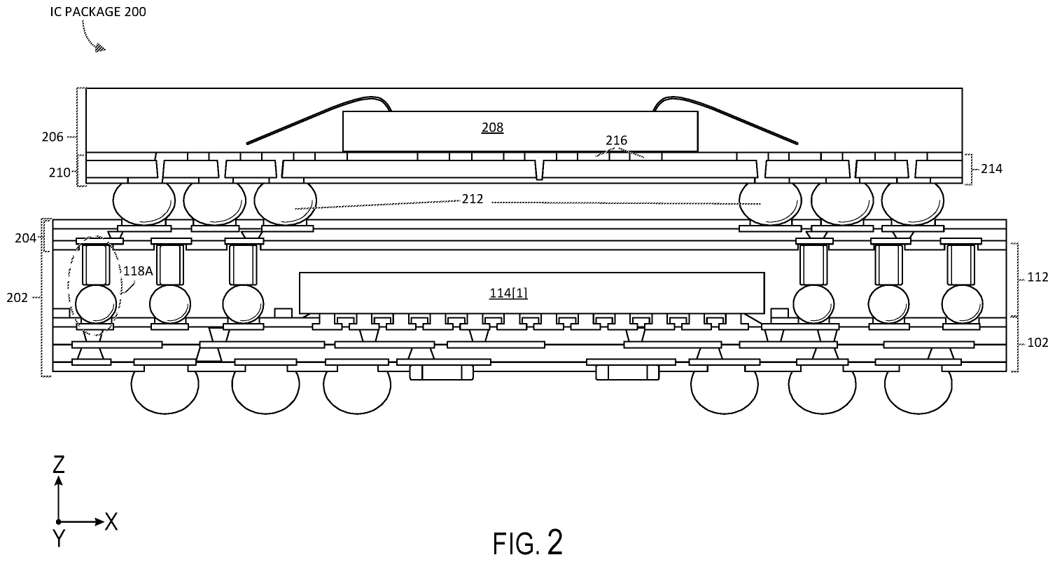

FIG. 2 is a side view of an exemplary package-on-package 3DIC package 200 that includes two substrates and vertical interconnects coupling the two substrates, the vertical interconnects 118A-118F comprising a metal ball and metal pin combination to address an increased distance between the two substrates. Common elements between the package 100 in FIGS. 1A and 1B and the package 200 in FIG. 2 are shown with common element numbers. The package-on-package 3DIC package 200 includes a first package 202 which includes a first package substrate 102, an interposer substrate 204, and a mold layer 112 between the first package substrate 102 and the interposer substrate 204. The mold layer 112 includes the first die 114(1) and the vertical interconnects 118A-118F which are coupled to the first package substrate 102.

The package-on-package 3DIC package 200 also includes a second package 206 which includes a second die 208, a second package substrate 210, and external interconnects 212. The second package substrate 210 includes metallization layers 214. The second die 208 is coupled to the interposer substrate 204 through die interconnects 216 coupled to the metallization layers 214 and through to the external interconnects 212.

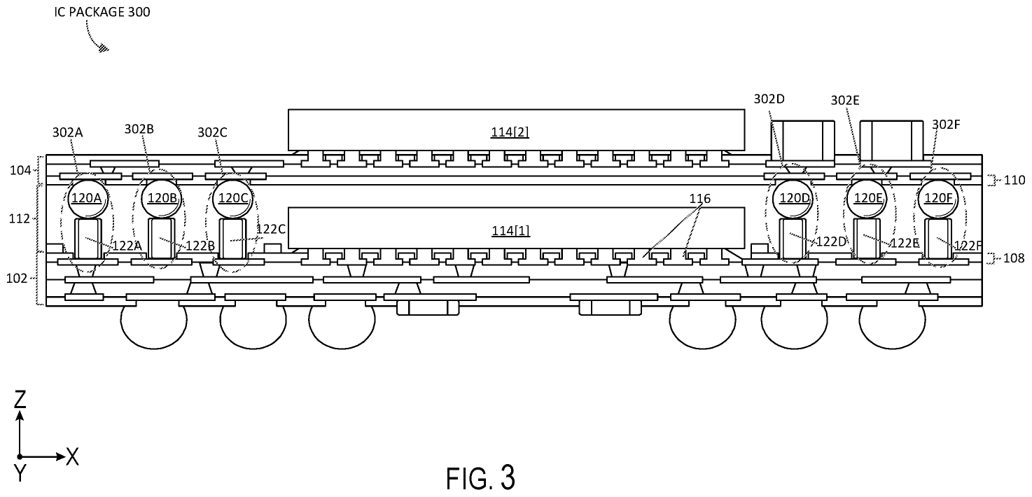

FIG. 3 is a side view of another exemplary 3DIC package 300 that includes two substrates and vertical interconnects coupling the two substrates, the vertical interconnects comprising a metal ball and metal pin combination to address an increased distance between the two substrates. Common elements between the package 100 in FIGS. 1A and 1B and the package 300 in FIG. 3 are shown with common element numbers.

The two substrates include a package substrate 102 and an interposer substrate 104, both of which extend in a first, horizontal direction (X-, Y-axes direction). The package substrate 102 and the interposer substrate 104 commonly route signals and power. The first, package substrate 102 includes a first, upper metallization layer 108 extending in the first, horizontal direction. The second, interposer substrate 104 includes a second, bottom metallization layer 110. A mold layer 112 extending in the first, horizontal direction includes a first die 114(1) coupled to one of the first substrate 102 or the second substrate 104. In this example, the first die 114(1) is coupled substrate 102 which is directly coupled to the plurality of pins 122A-122F. The first die 114(1) directly couples to the first, upper metallization layer 108 of the first substrate 102 through die interconnects 116. The mold layer 112 also includes vertical interconnects 302A-302F which are coupled to the package substrate 102 and to the interposer substrate 104. The vertical interconnects 302A-302F comprise a plurality of metal balls 120A-120F coupled to a plurality of metal pins 122A-122F. The plurality of metal balls 120A-120F are coupled second, bottom metallization layer 110 and, in particular, to metal interconnects 124 (e.g. pads) formed in the bottom metallization layer 110 of second, interposer substrate 104. The plurality of metal pins 122A-122F are coupled to the to the first, upper metallization layer 108 in the package substrate 102. Six vertical interconnects 302A-302F are shown for simplicity, but many more may exist between the first substrate 102 and the second substrate 104 and are limited by the width of the vertical interconnects 302A-302F which were discussed further in connection with FIG. 1B. The coupling between the metal balls 120A-120F and the metal pins 122A-122F was also discussed in connection with FIG. 1B.

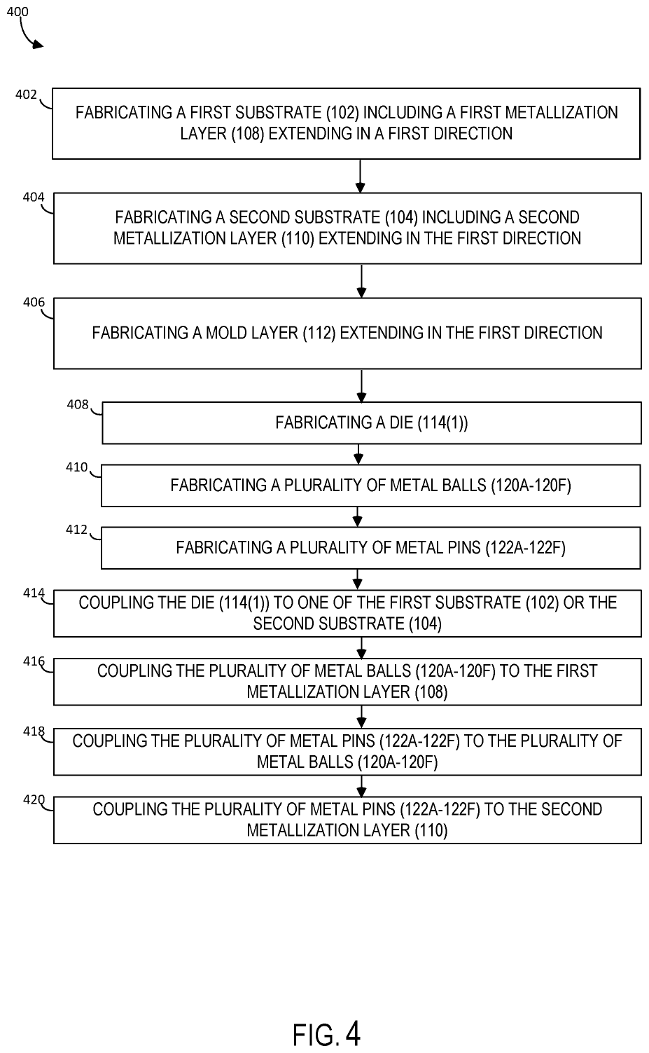

A package that includes two substrates and vertical interconnects coupling the two substrates, the vertical interconnects comprising a metal ball and metal pin combination to address an increased distance between the two substrates, including, but not limited to, the vertical interconnects in FIGS. 1A, 1B, 2, and deployed in the related IC packages 100, 200, and 300 in FIGS. 1A, 1B, 2 and 3 can be fabricated by different fabrication processes. FIG. 4 is a flowchart illustrating an exemplary fabrication process 400 of fabricating a 3DIC package such as the 3DIC packages in FIGS. 1A, 1B, 2, and 3 wherein the 3DIC package includes two substrates and vertical interconnects coupling the two substrates, the vertical interconnects comprising a metal ball and metal pin combination to address an increased distance between the two substrates, including, but not limited to, the 3DIC packages in FIGS. 1A, 1B, 2, and 3.

In this regard, a first exemplary step for fabricating a package that includes two substrates and vertical interconnects coupling the two substrates, the vertical interconnects comprising a metal ball and metal pin combination to address an increased distance between the two substrates in the fabrication process 400 of FIG. 4 can include fabricating a first substrate 102 including a first metallization layer 108 extending in a first direction (block 402 in FIG. 4). The next step in the fabrication process 400 can include fabricating a second substrate 104 including a second metallization layer 110 extending in the first direction (block 404 in FIG. 4). The next step in the fabrication process 400 can include fabricating a mold layer 112 extending in the first direction (block 406 in FIG. 4). Fabricating the mold layer 112 may include the following: fabricating a die 114(1) (block 408 in FIG. 4), fabricating a plurality of metal balls 120A-120F (block 410 in FIG. 4), and fabricating a plurality of metal pins 122A-122F (block 412 in FIG. 4). The next step in the fabrication process 400 can include coupling the die 114(1) to one of the first substrate 102 or the second substrate 104 (block 414 in FIG. 4). The next step in the fabrication process 400 can include coupling the plurality of metal balls 120A-120F to the first metallization layer 108 (block 416 in FIG. 4). The next step in the fabrication process 400 can include coupling the plurality of metal pins 122A-122F to the plurality of metal balls 120A-120F (block 418 in FIG. 4). The next step in the fabrication process 400 can include coupling the plurality of metal pins 122A-122F to the second metallization layer 110 (block 420 in FIG. 4).

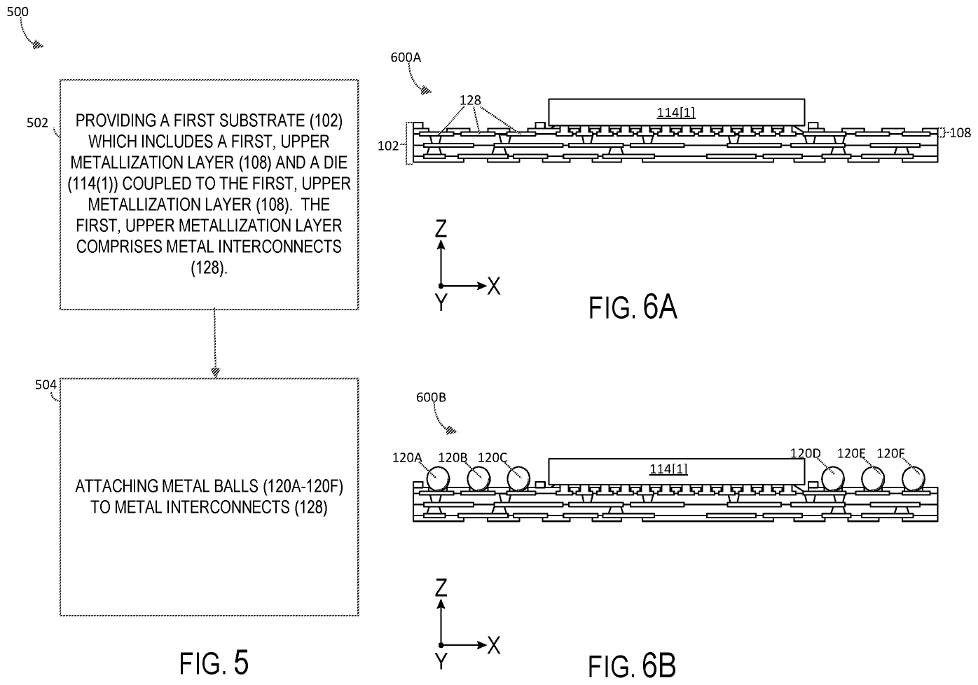

Other fabrication processes can also be employed to fabricate a package that includes two substrates and vertical interconnects coupling the two substrates, the vertical interconnects comprising a metal ball and metal pin combination to address an increased distance between the two substrates, including, but not limited to, the exemplary vertical interconnects 118A-118F in FIGS. 1A, 1B, and 2 and 302A-302F in FIG. 3 and in the related IC packages 100, 200, and 300 in FIGS. 1A, 1B, 2, and 3. In this regard, FIGS. 5, 7, and 9 include individual flowcharts to fabricate a first substrate with a plurality of balls, a second substrate with a plurality of pins, and a package which is assembled by coupling the first and second fabricated substrates.

FIG. 5 is a flowchart illustrating an exemplary fabrication process 500 of fabricating a first substrate, wherein the first substrate includes a plurality of metal balls for forming vertical interconnects which address an increased distance between two substrates, including, but not limited to, the increased distances in the 3DIC packages in FIGS. 1A, 1B, 2, and 3. FIGS. 6A-6B are exemplary fabrication stages 600A-600B during fabrication of the first substrate according to the fabrication process 500 in FIG. 5. The fabrication process 500 as shown in the fabrication stages 600A-600B in FIGS. 6A-6B will be discussed in reference to the package 100 and are equally applicable to the packages 200 and 300. The fabrication process 500 will be discussed from the perspective of creating one package. However, the fabrication process 500 may be performed at a wafer level where a wafer comprises a plurality of substrates to enable creating multiple packages before being singulated into individual packages.

In this regard, as shown in fabrication stage 600A in FIG. 6A, an exemplary step in the fabrication process 500 is providing a first substrate 102 which includes a first, upper metallization layer 108 and a die 114(1) coupled to the first, upper metallization layer 108. The first, upper metallization layer 108 comprises metal interconnects 128. (block 502 in FIG. 5). As shown in fabrication stage 600B in FIG. 6B, a next step in the fabrication process 500 can include attaching metal balls 120A-120F to the metal interconnects 128 (block 504 in FIG. 5).

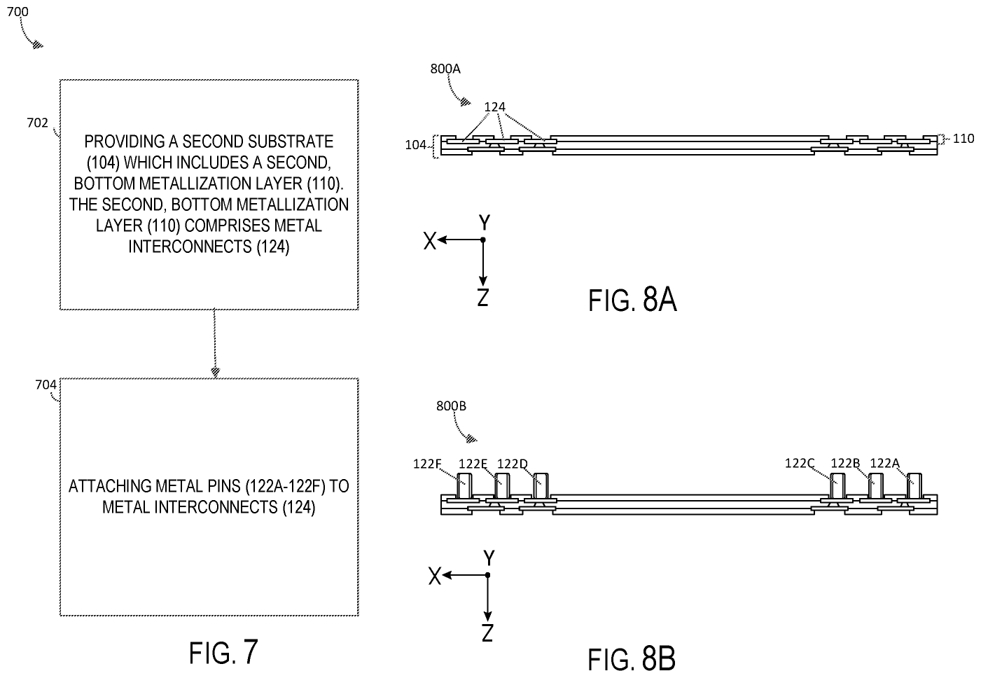

FIG. 7 is a flowchart illustrating an exemplary fabrication process 700 of fabricating a second substrate, wherein the second substrate includes a plurality of metal pins for forming vertical interconnects which address an increased distance between two substrates, including, but not limited to, the increased distances between substrates in the 3DIC packages in FIGS. 1A, 1B, 2, and 3. FIGS. 8A-8B are exemplary fabrication stages during fabrication of the second substrate according to the fabrication process in FIG. 7. The fabrication process 700 as shown in fabrication stages 800A-800B in FIGS. 8A-8B will be discussed in reference to the package 100 and are equally applicable to the packages 200 and 300.

In this regard, as shown in fabrication stage 800A in FIG. 8A, an exemplary step in the fabrication process 700 is providing a second substrate 104 (flipped 180° as compared to FIG. 1A) which includes a second, bottom metallization layer 110. The second, bottom metallization layer 110 comprises metal interconnects 124 (block 702 in FIG. 7). As shown in fabrication stage 800B in FIG. 8B, a next step in the fabrication process 700 can include attaching metal pins 122A-122F to the metal interconnects 124 (block 704 in FIG. 7).

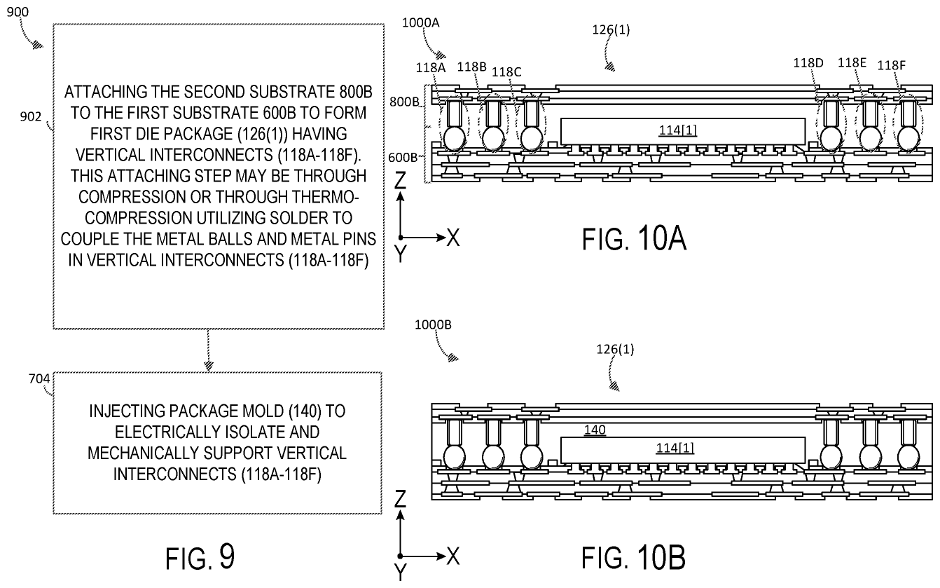

FIG. 9 is a flowchart illustrating an exemplary assembly process 900 of fabricating a package utilizing the first substrate 102 fabricated in FIG. 6B and the second substrate 104 fabricated in FIG. 8B to form a 3DIC package including, but not limited to, the 3DIC packages in 1A, 1B, 2, and 3 which include vertical interconnects having a metal ball and metal pin combination to address an increased distance between the two substrates. FIGS. 10A-10B are exemplary assembly stages during assembly of the substrate according to the fabrication process in FIG. 9.

In this regard, as shown in fabrication stage 1000A in FIG. 10A, an exemplary step in the fabrication process 900 is attaching the second substrate 800B in FIG. 8B (flipped 180° from FIG. 8B) to the first substrate 600B in FIG. 6B to form a first die package 126(1) having vertical interconnects 118A-118F. This attaching step may be through compression or through thermo-compression utilizing solder to couple the metal balls 120A-120F and the metal pins 122A-122F in the vertical interconnects 118A-118F (block 902 in FIG. 9). As shown in fabrication stage 1000B in FIG. 10B, a next step in the fabrication process 900 can include injecting a package mold 140 to electrically isolate and mechanically support the vertical interconnects 118A-118F (block 904 in FIG. 9).

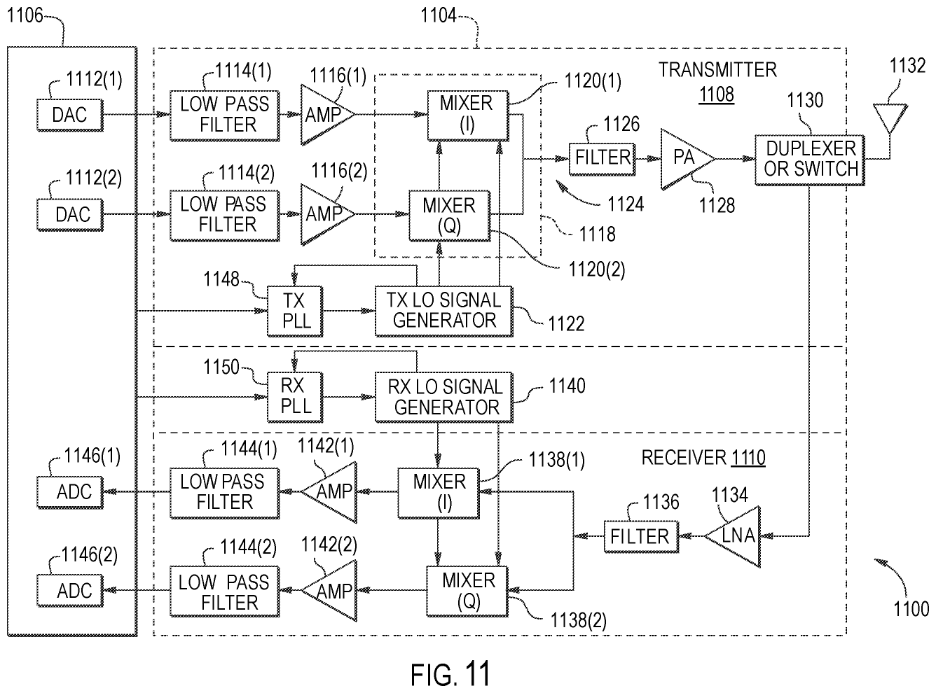

FIG. 11 is a block diagram of an exemplary wireless communications device that includes radio-frequency (RF) components deployed in an IC package, wherein the IC package includes two substrates and vertical interconnects coupling the two substrates, the vertical interconnects comprising a metal ball and metal pin combination to address an increased distance between the two substrates, including, but not limited to, the 3DIC package in FIGS. 1A, 1B, 2, and 3 and according to the exemplary fabrication processes in FIGS. 4, 5, 7, and 9, and according to any exemplary aspects disclosed herein. The wireless communications device 1100 may include or be provided in any of the above-referenced devices, as examples. As shown in FIG. 11, the wireless communications device 1100 includes a transceiver 1104 and a data processor 1106. The data processor 1106 may include a memory to store data and program codes. The transceiver 1104 includes a transmitter 1108 and a receiver 1110 that support bi-directional communications. In general, the wireless communications device 1100 may include any number of transmitters 1108 and/or receivers 1110 for any number of communication systems and frequency bands. All or a portion of the transceiver 1104 may be implemented on one or more analog ICs, RF ICs (RFICs), mixed-signal ICs, etc.

The transmitter 1108 or the receiver 1110 may be implemented with a super-heterodyne architecture or a direct-conversion architecture. In the super-heterodyne architecture, a signal is frequency-converted between RF and baseband in multiple stages, for example, from RF to an intermediate frequency (IF) in one stage, and then from IF to baseband in another stage for the receiver 1110. In the direct-conversion architecture, a signal is frequency-converted between RF and baseband in one stage. The super-heterodyne and direct-conversion architectures may use different circuit blocks and/or have different requirements. In the wireless communications device 1100 in FIG. 11, the transmitter 1108 and the receiver 1110 are implemented with the direct-conversion architecture.

In the transmit path, the data processor 1106 processes data to be transmitted and provides I and Q analog output signals to the transmitter 1108. In the exemplary wireless communications device 1100, the data processor 1106 includes digital-to-analog converters (DACs) 1112(1), 1112(2) for converting digital signals generated by the data processor 1106 into the I and Q analog output signals (e.g., I and Q output currents) for further processing.

Within the transmitter 1108, lowpass filters 1114(1), 1114(2) filter the I and Q analog output signals, respectively, to remove undesired signals caused by the prior digital-to-analog conversion. Amplifiers (AMPs) 1116(1), 1116(2) amplify the signals from the lowpass filters 1114(1), 1114(2), respectively, and provide I and Q baseband signals. An upconverter 1118 upconverts the I and Q baseband signals with I and Q transmit (TX) local oscillator (LO) signals through mixers 1120(1), 1120(2) from a TX LO signal generator 1122 to provide an upconverted signal 1124. A filter 1126 filters the upconverted signal 1124 to remove undesired signals caused by the frequency up-conversion as well as noise in a receive frequency band. A power amplifier (PA) 1128 amplifies the upconverted signal 1124 from the filter 1126 to obtain the desired output power level and provides a transmit RF signal. The transmit RF signal is routed through a duplexer or switch 1130 and transmitted via an antenna 1132.

In the receive path, the antenna 1132 receives signals transmitted by base stations and provides a received RF signal, which is routed through the duplexer or switch 1130 and provided to a low noise amplifier (LNA) 1134. The duplexer or switch 1130 is designed to operate with a specific receive (RX)-to-TX duplexer frequency separation, such that RX signals are isolated from TX signals. The received RF signal is amplified by the LNA 1134 and filtered by a filter 1136 to obtain a desired RF input signal. Down-conversion mixers 1138(1), 1138(2) mix the output of the filter 1136 with I and Q RX LO signals (i.e., LO_I and LO_Q) from an RX LO signal generator 1140 to generate I and Q baseband signals. The I and Q baseband signals are amplified by AMPs 1142(1), 1142(2) and further filtered by lowpass filters 1144(1), 1144(2) to obtain I and Q analog input signals, which are provided to the data processor 1106. In this example, the data processor 1106 includes analog-to-digital converters (ADCs) 1146(1), 1146(2) for converting the analog input signals into digital signals to be further processed by the data processor 1106.

In the wireless communications device 1100 of FIG. 11, the TX LO signal generator 1122 generates the I and Q TX LO signals used for frequency up-conversion, while the RX LO signal generator 1140 generates the I and Q RX LO signals used for frequency down-conversion. Each LO signal is a periodic signal with a particular fundamental frequency. A TX phase-locked loop (PLL) circuit 1148 receives timing information from the data processor 1106 and generates a control signal used to adjust the frequency and/or phase of the TX LO signals from the TX LO signal generator 1122. Similarly, an RX PLL circuit 1150 receives timing information from the data processor 1106 and generates a control signal used to adjust the frequency and/or phase of the RX LO signals from the RX LO signal generator 1140.

Electronic devices that include an IC package, wherein the IC package includes two substrates and vertical interconnects coupling the two substrates, the vertical interconnects comprising a metal ball and metal pin combination to address an increased distance between the two substrates, including, but not limited to, the increased distance between substrates in the 3DIC packages in FIGS. 1A, 1B, 2, and 3 in the related IC packages 100, 200, and 300 in FIGS. 1A, 1B, 2, and 3 and that can be fabricated according to, but not limited to, the exemplary fabrication processes in FIGS. 4, 5, 7, and 9, and according to any aspects disclosed herein, may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, laptop computer, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, and a multicopter.

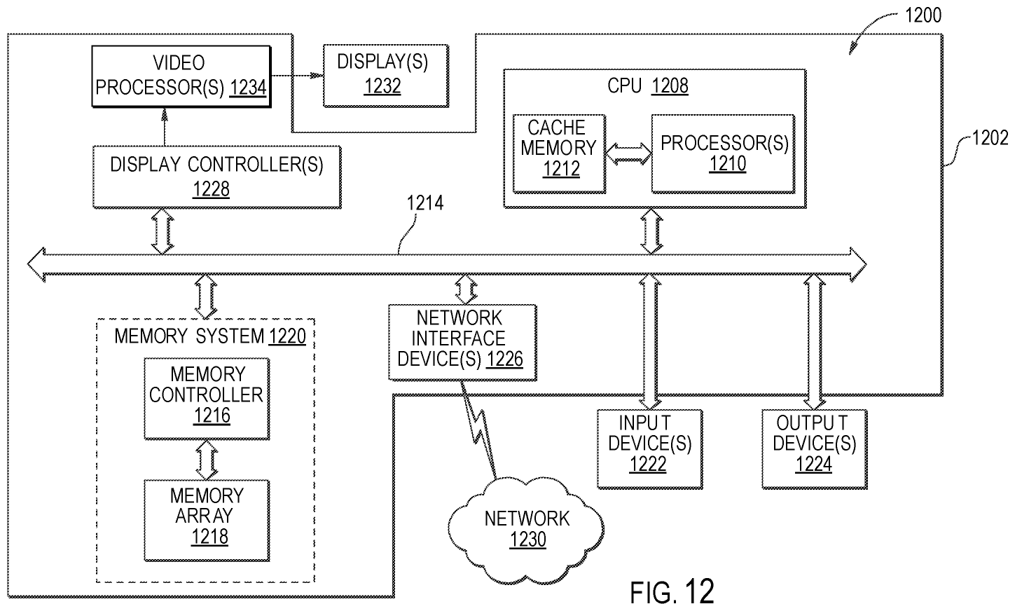

In this regard, FIG. 12 is a block diagram of an exemplary processor-based system that can include components deployed in an IC package, wherein the IC package includes two substrates and vertical interconnects coupling the two substrates, the vertical interconnects comprising a metal ball and metal pin combination to address an increased distance between the two substrates, including, but not limited to, the 3DIC packages in FIGS. 1A, 1B, 2, and 3 and according to the exemplary fabrication processes in FIGS. 4, 5, 7, and 9, and according to any exemplary aspects disclosed herein. In this example, the processor-based system 1200 may be formed as an IC package 1202 such as the IC package 200 in FIG. 2. The processor-based system 1200 includes a central processing unit (CPU) 1208 that includes one or more processors 1210, which may also be referred to as CPU cores or processor cores. The CPU 1208 may have cache memory 1212 coupled to the CPU 1208 for rapid access to temporarily stored data. The CPU 1208 is coupled to a system bus 1214 and can intercouple master and slave devices included in the processor-based system 1200. As is well known, the CPU 1208 communicates with these other devices by exchanging address, control, and data information over the system bus 1214. For example, the CPU 1208 can communicate bus transaction requests to a memory controller 1216, as an example of a slave device. Although not illustrated in FIG. 12, multiple system buses 1214 could be provided, wherein each system bus 1214 constitutes a different fabric.

Other master and slave devices can be connected to the system bus 1214. As illustrated in FIG. 12, these devices can include a memory system 1220 that includes the memory controller 1216 and a memory array(s) 1218, one or more input devices 1222, one or more output devices 1224, one or more network interface devices 1226, and one or more display controllers 1228, as examples. Each of the memory system(s) 1220, the one or more input devices 1222, the one or more output devices 1224, the one or more network interface devices 1226, and the one or more display controllers 1228 can be provided in the same or different electronic devices. The input device(s) 1222 can include any type of input device, including, but not limited to, input keys, switches, voice processors, etc. The output device(s) 1224 can include any type of output device, including, but not limited to, audio, video, other visual indicators, etc. The network interface device(s) 1226 can be any device configured to allow exchange of data to and from a network 1230. The network 1230 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1226 can be configured to support any type of communications protocol desired.

The CPU 1208 may also be configured to access the display controller(s) 1228 over the system bus 1214 to control information sent to one or more displays 1232. The display controller(s) 1228 sends information to the display(s) 1232 to be displayed via one or more video processor(s) 1234, which process the information to be displayed into a format suitable for the display(s) 1232. The display controller(s) 1228 and video processor(s) 1234 can be included as ICs in the same or different electronic devices, and in the same or different electronic devices containing the CPU 1208, as an example. The display(s) 1232 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:

1. An integrated circuit (IC) package, comprising:
a first substrate comprising:
   a first metallization layer extending in a first direction;
a second substrate comprising:
   a second metallization layer extending in the first direction; and
a mold layer extending in the first direction, comprising:
   a die coupled to one of the first substrate or the second substrate;
   a plurality of metal balls coupled to the first metallization layer; and
   a plurality of metal pins coupled to the plurality of metal balls, the plurality of metal pins coupled to the second metallization layer.
      2. The IC package of clause 1, wherein the die is coupled to the first metallization layer.
      3. The IC package of clause 1, wherein the die is coupled to the second metallization layer.
      4. The IC package of any of clauses 1-3, further comprising a plurality of solder joints between the plurality of metal pins and the plurality of metal balls.
      5. The IC package of any of clauses 1-3, further comprising a plurality of compression joints between the plurality of metal pins and the plurality of metal balls.
      6. The IC package of any of clauses 1-5, wherein one of the plurality of metal balls is aligned with one of the plurality of metal pins along a common axis in a second direction.
      7. The IC package of any of clauses 1-6, wherein the plurality of metal balls have a diameter which is less than a first distance between the first metallization layer and the second metallization layer.
      8. The IC package of clause 7, wherein each of the plurality of metal pins has a length in a second direction less than the first distance.
      9. The IC package of clause 7 or 8, wherein the first metallization layer comprises a plurality of metal pads, the plurality of metal balls coupled to the plurality of metal pads, the plurality of metal pads having a width approximately equal to the diameter of the plurality of metal balls.
      10. The IC package of any of clauses 1-9, wherein the plurality of metal balls are copper and the plurality of metal pins are copper.
      11. The IC package of any of clauses 1-10 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; and a multicopter.
      12. A method of fabricating an integrated circuit (IC) package for addressing an increased distance between two substrates, comprising:
fabricating a first substrate including a first metallization layer extending in a first direction;
fabricating a second substrate including a second metallization layer extending in the first direction;
fabricating a mold layer extending in the first direction comprising:
   fabricating a die;
   fabricating a plurality of metal balls; and
   fabricating a plurality of metal pins;
coupling the die to one of the first substrate or the second substrate;
coupling the plurality of metal balls to the first metallization layer;
coupling the plurality of metal pins to the plurality of metal balls; and
coupling the plurality of metal pins to the second metallization layer.
   13. The method of clause 12, wherein coupling the die to the one of the first substrate or the second substrate further comprises coupling to the first metallization layer.
   14. The method of clause 12, wherein coupling the die to the one of the first substrate or the second substrate further comprises coupling to the second metallization layer.
   15. The method of any of clauses 12-14, wherein coupling the plurality of metal pins to the plurality of metal balls further comprises soldering the plurality of metal pins to the plurality of metal balls.
   16. The method of any of clauses 12-14, wherein coupling the plurality of metal pins to the plurality of metal balls further comprises compressing the plurality of metal pins to the plurality of metal balls.
   17. The method of any of clauses 12-16, wherein coupling the plurality of metal pins to the plurality of metal balls further comprises aligning one of the plurality of metal balls with one of the plurality of metal pins along a common axis in a second direction.
   18. The method of any of clauses 12-17, wherein the plurality of metal balls have a diameter which is less than a first distance between the first metallization layer and the second metallization layer.
   19. The method of clause 18, wherein each of the plurality of metal pins has a length in a second direction less than the first distance.
   20. The method of clause 18 or 19, wherein the first metallization layer comprises a plurality of metal pads, the plurality of metal balls coupled to the plurality of metal pads, the plurality of metal pads having a width approximately equal to the diameter of the plurality of metal balls.

What is claimed is:

1. An integrated circuit (IC) package, comprising:
a first substrate comprising:
a first metallization layer extending in a first direction;
a second substrate comprising:
a second metallization layer extending in the first direction; and
a mold layer extending in the first direction, comprising:
a die coupled to one of the first substrate or the second substrate;
a plurality of metal balls coupled to the first metallization layer; and
a plurality of metal pins coupled to the plurality of metal balls, the plurality of metal pins coupled to the second metallization layer.

2. The IC package of claim 1, wherein the die is coupled to the first metallization layer.

3. The IC package of claim 1, wherein the die is coupled to the second metallization layer.

4. The IC package of claim 1, further comprising a plurality of solder joints between the plurality of metal pins and the plurality of metal balls.

5. The IC package of claim 1, further comprising a plurality of compression joints between the plurality of metal pins and the plurality of metal balls.

6. The IC package of claim 1, wherein one of the plurality of metal balls is aligned with one of the plurality of metal pins along a common axis in a second direction.

7. The IC package of claim 1, wherein the plurality of metal balls have a diameter which is less than a first distance between the first metallization layer and the second metallization layer.

8. The IC package of claim 7, wherein each of the plurality of metal pins has a length in a second direction less than the first distance.

9. The IC package of claim 7, wherein the first metallization layer comprises a plurality of metal pads, the plurality of metal balls coupled to the plurality of metal pads, the plurality of metal pads having a width approximately equal to the diameter of the plurality of metal balls.

10. The IC package of claim 1, wherein the plurality of metal balls are copper and the plurality of metal pins are copper.

11. The IC package of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; and a multicopter.

12. A method of fabricating an integrated circuit (IC) package for addressing an increased distance between two substrates, comprising:
fabricating a first substrate including a first metallization layer extending in a first direction;
fabricating a second substrate including a second metallization layer extending in the first direction;
fabricating a mold layer extending in the first direction comprising:
fabricating a die;
fabricating a plurality of metal balls; and
fabricating a plurality of metal pins;
coupling the die to one of the first substrate or the second substrate;
coupling the plurality of metal balls to the first metallization layer;
coupling the plurality of metal pins to the plurality of metal balls; and
coupling the plurality of metal pins to the second metallization layer.

13. The method of claim 12, wherein coupling the die to the one of the first substrate or the second substrate further comprises coupling to the first metallization layer.

14. The method of claim 12, wherein coupling the die to the one of the first substrate or the second substrate further comprises coupling to the second metallization layer.

15. The method of claim 12, wherein coupling the plurality of metal pins to the plurality of metal balls further comprises soldering the plurality of metal pins to the plurality of metal balls.

16. The method of claim 12, wherein coupling the plurality of metal pins to the plurality of metal balls further comprises compressing the plurality of metal pins to the plurality of metal balls.

17. The method of claim 12, wherein coupling the plurality of metal pins to the plurality of metal balls further comprises aligning one of the plurality of metal balls with one of the plurality of metal pins along a common axis in a second direction.

18. The method of claim 12, wherein the plurality of metal balls have a diameter which is less than a first distance between the first metallization layer and the second metallization layer.

19. The method of claim 18, wherein each of the plurality of metal pins has a length in a second direction less than the first distance.

20. The method of claim 18, wherein the first metallization layer comprises a plurality of metal pads, the plurality of metal balls coupled to the plurality of metal pads, the plurality of metal pads having a width approximately equal to the diameter of the plurality of metal balls.
